(19) United States
(12) Patent Application Publication
(10) Pub. No.: US 2025/0240918 A1
(43) Pub. Date: Jul. 24, 2025

(54) LIQUID LEAKAGE PROTECTION DEVICE

(71) Applicant: SHENZHEN ENVICOOL TECHNOLOGY CO., LTD., Shenzhen (CN)

(72) Inventors: Xiaoxin XU, Shenzhen (CN); Xiaolei AI, Shenzhen (CN); Zhen XIONG, Shenzhen (CN); Xiaojin CHENG, Shenzhen (CN)

(73) Assignee: SHENZHEN ENVICOOL TECHNOLOGY CO., LTD., Shenzhen (CN)

(21) Appl. No.: 18/806,087

(22) Filed: Aug. 15, 2024

(30) Foreign Application Priority Data
Jan. 19, 2024 (CN) 202410084899.3

(51) Int. Cl. H05K 7/20

(52) U.S. Cl. CPC H05K 7/20272; H05K 7/20254

(57) ABSTRACT

A liquid leakage protection device is provided in the present application. The liquid leakage protection device includes a cold plate including a heated plate and a cover plate, which are connected to form a liquid-cooling chamber for accommodating a liquid-cooling medium. The liquid leakage protection device further includes an enclosure structure arranged outside the liquid-cooling chamber, which can block the liquid-cooling medium leaking from the liquid-cooling chamber from flowing to a working component in contact with the heated plate, thereby preventing damage to the working component and influence on the data security. Meanwhile, the enclosure structure and the cold plate form a liquid reservoir to store the liquid-cooling medium leaking from the liquid-cooling chamber, which can ensure a sufficient time for data storage after the liquid-cooling medium leaks and for safe shutdown of the equipment.

### CROSS REFERENCE TO RELATED APPLICATIONS

The present application claims priority to Chinese Patent Application No. 202410084899.3, titled “LIQUID LEAKAGE PROTECTION DEVICE”, filed on Jan. 19, 2024 with the China National Intellectual Property Administration, which is incorporated herein by reference in its entirety.

### FIELD

The present disclosure relates to the technical field of cold-plate liquid cooling, and in particular to a liquid leakage protection device.

### BACKGROUND

At present, a cold-plate liquid cooling technology has become a prevailing cooling technology for servers.

In the existing system, a cold plate is used as a core component of the cold-plate liquid cooling device to contact working components such as a mainboard. The liquid-cooling medium flows in the cold plate by connecting a pipeline or providing a flowing channel. The advantage of using such heat dissipation method is to replace a traditional convective heat exchange between air and the mainboard (heat exchange by a fan) with a convective heat exchange and a thermal conduction from the liquid-cooling medium through the cold plate to the mainboard, which greatly increases the convective heat-exchange coefficient and is significantly beneficial to a heat dissipation of the mainboard.

In a process of making the present invention, the inventors have found that there are at least the following problems in the existing technology:

The manufacturing defects of the cold plate result in a high risk of liquid leakage which occurs at the position of the cold plate in the entire cold-plate liquid cooling device. The liquid-cooling medium leaking from the cold plate could pose a great threat to the hardware and data security of the server. The conventional solution for a leakage is to power off and shut down the entire server equipment in an emergency once the leakage is detected. However, the emergency power-off operation on the server equipment may still cause damage to the hardware of the server and affect the data security.

Therefore, it is necessary for those skilled in the art to timely provide a liquid leakage protection device that can ensure a safe shutdown of the server equipment.

### SUMMARY

An object of the present disclosure is to provide a liquid leakage protection device, which can collect the liquid-cooling medium leaking from the cold plate so as to ensure that the equipment can be safely shut down.

In order to achieve the above object, a liquid leakage protection device is provided in the present disclosure, and includes a cold plate and an enclosure structure. The cold plate includes a heated plate and a cover plate. The heated plate and the cover plate are connected to form a liquid-cooling chamber for accommodating a liquid-cooling medium. The enclosure structure is arranged at an outer periphery of the liquid-cooling chamber to block the liquid-cooling medium leaking from the liquid-cooling chamber from flowing to a working component in contact with the heated plate. The enclosure structure and the cold plate form a liquid reservoir, so that the liquid-cooling medium leaking from the liquid-cooling chamber can be stored in the liquid reservoir.

In some embodiments, a flow-guiding passage is further formed by the enclosure structure and the cold plate and is in communication with the liquid reservoir, and the liquid-cooling medium leaking from the liquid-cooling chamber flows into the liquid reservoir after being guided through the flow-guiding passage.

In some embodiments, the enclosure structure includes:
a perimeter wall, which is arranged around the cover plate to form the liquid reservoir; and
a blocking part connected to a bottom of the perimeter wall so as to form the flow-guiding passage and block a path along which the liquid-cooling medium in the liquid-cooling chamber leaks to the working component.

In some embodiments, the blocking part includes:
an outer edge, which is arranged on the heated plate and extends beyond the cover plate;
a shielding plate, which is located on an outer periphery of the perimeter wall and abuts against the outer edge; and
a seal retainer ring, which is sandwiched between the outer edge and the shielding plate to seal a gap between the outer edge and the shielding plate.

In some embodiments, a mounting groove is provided on the outer edge. The seal retainer ring is mounted in the mounting groove, and the mounting groove has a depth less than a thickness of the seal retainer ring.

In some embodiments, the shielding plates are distributed on four sides of the perimeter wall, and a size of the shielding plates on both sides of the perimeter wall in a first direction is greater than that of the shielding plates on both sides of the perimeter wall in a second direction, so that the shielding plates can cover the working component to prevent a liquid-cooling medium leaking from a pipeline connected to the cold plate from splashing onto the working component when dripping down to the liquid reservoir.

In some embodiments, the liquid leakage protection device further includes a cover. The cover is located on and covers the perimeter wall to prevent the liquid-cooling medium in the liquid reservoir from leaking to the outside.

In some embodiments, the liquid leakage protection device further includes a suction mechanism, which is connected to the liquid reservoir to draw the liquid-cooling medium out of the liquid reservoir, where the suction mechanism includes:
a liquid suction tube having one end which extends into the liquid reservoir;
a liquid suction assembly, which is connected to the liquid suction tube to draw the liquid-cooling medium out of the liquid reservoir through the liquid suction tube;
a leakage detection member, which is located in the liquid reservoir to detect an amount of the liquid-cooling medium in the liquid reservoir; and
a control assembly, which is electrically connected to the leakage detection member and the liquid suction assembly to control the liquid suction assembly to start and draw the liquid-cooling medium out of the liquid reservoir when the amount of the liquid-cooling medium in the liquid reservoir exceeds a warning amount.

In some embodiments, a liquid collection groove and a guide slope located around the liquid collection groove are provided on the cover plate. The liquid-cooling medium on the cover plate is guided by the guide slope and then collected into the liquid collection groove. The liquid suction tube extends into the liquid collection groove.

In some embodiments, the leakage detection member is of a sheet-like structure, which covers a surface of the cover plate away from the heated plate.

Compared to the existing technology, the liquid leakage protection device provided in the embodiments of the present disclosure includes a cold plate including a heated plate and a cover plate which are connected to form a liquid-cooling chamber for accommodating a liquid-cooling medium, and the liquid leakage protection device further includes an enclosure structure arranged to surround the liquid-cooling chamber. On the one hand, the enclosure structure located outside the liquid-cooling chamber blocks the liquid-cooling medium leaking from the liquid-cooling chamber from flowing to the working component in contact with the heated plate, thereby preventing damage to the working component and influence on the data security. On the other hand, the enclosure structure and the cold plate form a liquid reservoir to store the liquid-cooling medium leaking from the liquid-cooling chamber, which can ensure a sufficient time for data storage after the liquid-cooling medium leaks and for a subsequent safe shutdown of the equipment. Compared to the conventional solution, the liquid leakage protection device provided in the embodiments of the present disclosure blocks and collects leaking liquid at a position of the cold plate having a high risk of leakage, thereby not only ensuring that the server equipment can be safely shut down but also protecting the hardware and data security of the server

### BRIEF DESCRIPTION OF THE DRAWINGS

In order to provide a clear explanation of the embodiments of the present disclosure or the technical solutions in the prior art, a brief introduction will be given to the accompanying drawings required for the description of the embodiments or the prior art. Obviously, the accompanying drawings described below only illustrate some embodiments of the present disclosure. For those skilled in the art, other drawings can be obtained based on these drawings without paying a creative work.

FIG. 1 is a schematic structural view of a liquid leakage protection device according to an embodiment of the present disclosure;

FIG. 2 is a top view of the liquid leakage protection device in FIG. 1;

FIG. 3 is a cross-sectional view of the liquid leakage protection device in FIG. 1;

FIG. 4 is a front view of FIG. 3;

FIG. 5 is a schematic structural view of an assembly of the liquid leakage protection device in FIG. 1 and a cover;

FIG. 6 is a schematic view of use of the liquid leakage protection device according to an embodiment of the present disclosure; and

FIG. 7 is a top view of FIG. 6.

In accompany drawings:
1 liquid leakage protection device,
11 cold plate, 12 enclosure structure, 13 liquid reservoir, 14 flow-guiding passage, 15 cover, 16 suction mechanism,
111 heated plate, 112 cover plate, 113 liquid-cooling chamber,
121 perimeter wall, 122 blocking part,
1221 outer edge, 1222 shielding plate, 1223 seal retainer ring,
12211 mounting groove.

### DETAILED DESCRIPTION OF THE EMBODIMENTS

The technical solution in the embodiments of the present disclosure will be clearly and completely described in conjunction with the accompanying drawings below. Obviously, the described embodiments are only a part of the embodiments of the present disclosure, not all of them. Based on the embodiments in the present disclosure, all other embodiments obtained by those skilled in the art without creative works will fall within the scope of the present disclosure.

In order to better understand the solution of the present disclosure for those skilled in the art, a further detailed explanation of the present disclosure is provided below in conjunction with the accompanying drawings and specific embodiments.

It should be noted that the directional words such as “upper end”, “lower end”, “left side”, and “right side” mentioned below are defined based on the accompanying drawings of the specification.

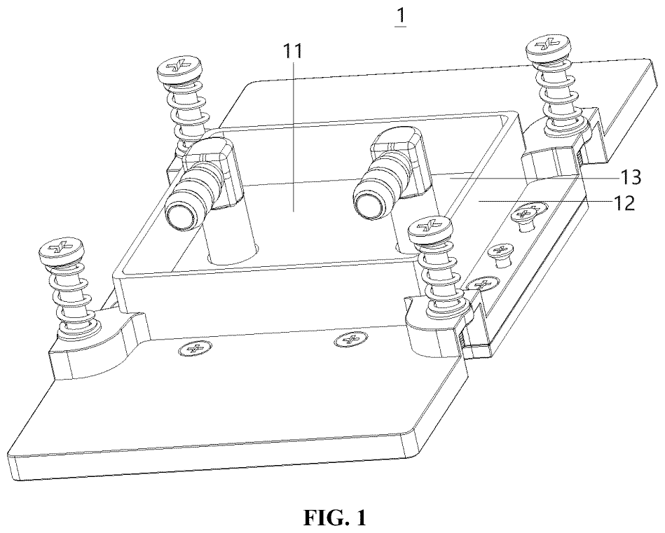

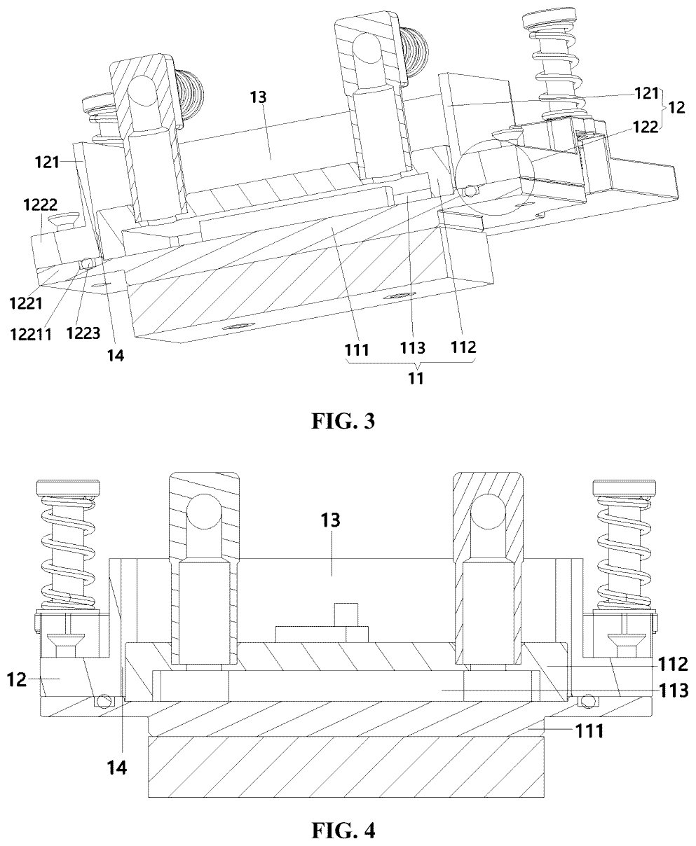

Referring to FIGS. 1 to 4, a liquid leakage protection device 1 provided in an embodiment of the present disclosure includes a cold plate 11. The cold plate 11 includes a heated plate 111 and a cover plate 112. The heated plate 111 and the cover plate 112 are connected to form a liquid-cooling chamber 113 for accommodating a liquid-cooling medium.

It should be noted that, in this embodiment, the cold plate 11 is formed by welding the heated plate 111 to the cover plate 112. Due to the limitation of welding process, a weld seam (also known as a leakage gap) may be formed after joining the heated plate 111 to the cover plate 112, causing the liquid-cooling medium in the liquid-cooling chamber 113 to leak out from the leakage gap.

In view of this, the liquid leakage protection device 1 further includes an enclosure structure 12, which is located outside of the liquid-cooling chamber 113 to block the liquid-cooling medium leaking from the liquid-cooling chamber 113 from flowing to a working component in contact with the heated plate 111. Furthermore, the enclosure structure 12 and the cold plate 11 form a liquid reservoir 13, so that the liquid-cooling medium leaking from the liquid-cooling chamber 113 can be stored in the liquid reservoir 13.

On one hand, the enclosure structure 12 located around the liquid-cooling chamber 113 blocks the liquid-cooling medium leaking from the liquid-cooling chamber 113 from flowing to the working component in contact with the heated plate 111, thereby preventing damage to the working component and impact on the data security. On the other hand, the enclosure structure 12 and the cold plate 11 form a liquid reservoir 13 to store the liquid-cooling medium leaking from the liquid-cooling chamber 113, which can ensure a sufficient time for data storage and subsequent safe shutdown of the equipment after the liquid-cooling medium leaks.

Compared to the conventional ways, the liquid leakage protection device 1 provided in the embodiment of the present disclosure functions to block and collect leaking liquid at the location of the cold plate 11 having a high risk of leakage, thereby not only ensuring that the server equipment can be safely shut down but also protecting the hardware and data security of the server.

In some embodiments, the liquid reservoir 13 may be located outside and adjacent to the cold plate 11. As such, the liquid-cooling medium in the liquid-cooling chamber 113 can be directly stored in the liquid reservoir 13 after leaking from the cold plate 11.

In some embodiments, the liquid reservoir 13 is located above the cover plate 112. Further, a flow-guiding passage 14 that is in communication with the liquid reservoir 13 is formed by the enclosure structure 12 and the cold plate 11. As such, the liquid-cooling medium leaking from the liquid-cooling chamber 113 flows into the liquid reservoir 13 after being channeled through the flow-guiding passage 14.

Hereinafter, the liquid reservoir 13 being positioned above the cover plate 112 is taken as an example for specific illustration.

The enclosure structure 12 includes a perimeter wall 121 and a blocking part 122. The perimeter wall 121 is arranged around the cover plate 112, and the liquid reservoir 13 is defined by the perimeter wall 121 and the cover plate 112. The perimeter wall 121 is of an enclosed rectangular structure, and surrounds the outer periphery of the cover plate 112. As such, it is equivalent to establish a fence structure outside the cover plate 112, facilitating storage of the leaking liquid-cooling medium on the cover plate 112. The blocking part 122 is connected to the bottom of the perimeter wall 121. A flow-guiding passage 14 is formed by the blocking part 122 and the cold plate 11. The blocking part 122 is configured to block a path along which the liquid-cooling medium in the liquid-cooling chamber 113 leaks to the working component.

In other words, the cover plate 112 serves as a bottom surface of the liquid reservoir 13 and the perimeter wall 121 serves as a side surface of the liquid reservoir 13, thereby forming a liquid storage structure with an open upper end.

It can be seen that the whole blocking part 122 and a part of the perimeter wall 121 surround the outer periphery of the cover plate 112 so as to, together with the cold plate 11, form the flow-guiding passage 14. The flow-guiding passage 14 may be a gap between the enclosure structure 12 and the cold plate 11. One end of the flow-guiding passage 14 extends to the leakage gap of the cold plate 11, and the other end extends to the liquid reservoir 13. The two ends of the flow-guiding passage 14 are in communication with the leakage gap of the cold plate 11 and the liquid reservoir 13, respectively. As such, the liquid-cooling medium leaking from the liquid-cooling chamber 113 is guided through the flow-guiding passage 14 to flow into the liquid reservoir 13.

According to actual needs, all or most of the structure of the flow-guiding passage 14 may be arranged longitudinally or vertically, or a small part of the flow-guiding passages 14 may be arranged transversely or horizontally. A longitudinal part of the flow-guiding passage 14 may be a gap between the enclosure structure 12 and the cover plate 112, and a transverse part of the flow-guiding passage 14 may be a gap between a step surface of the heated plate 111 and the cover plate 112. The step surface of the heated plate 111 is configured to further prevent the liquid-cooling medium in the liquid-cooling chamber 113 from leaking to the outside.

In some embodiments, the blocking part 122 includes an outer edge 1221, a shielding plate 1222, and a seal retainer ring 1223. The outer edge 1221 is arranged on the heated plate 111 and extends beyond the cover plate 112. The shielding plate 1222 is located on the outer periphery of the perimeter wall 121 and abuts against the outer edge 1221. The seal retainer ring 1223 is compressed between the outer edge 1221 and the shielding plates 1222 to seal a gap between the outer edge 1221 and the shielding plate 1222.

It can be seen that the blocking part 122, which is formed by the seal retainer ring 1223, the outer edge 1221, and the shielding plates 1222, is of a sealing structure. The liquid-cooling medium leaking from the liquid-cooling chamber 113 cannot flow through this sealing structure, thereby achieving a purpose of blocking the path along which the liquid-cooling medium in the liquid-cooling chamber 113 leaks to the working component.

That is, the liquid-cooling medium leaking from the liquid-cooling chamber 113 flows on an upper surface of the heated plate 111. Due to presence of the blocking part 122 formed by the seal retainer ring 1223, the outer edge 1221, and the shielding plates 1222, it can ensure that the liquid-cooling medium cannot leak to the working component below the heated plate 111, thereby ensuring the wording stability of the working component.

In order to facilitate mounting of the seal retainer ring 1223, a mounting groove 12211 may be provided on the outer edge 1221 to receive the seal retainer ring 1223. The mounting groove 12211 has a depth less than the thickness of the seal retainer ring 1223. As such, after being mounted, the seal retainer ring 1223 is compressed due to its own elasticity, thereby ensuring seal of the gap between the outer edge 1221 and the shielding plate 1222.

The above-mentioned shielding plates 1222 may be arranged on four sides of the perimeter wall 121. A size of the shielding plates 1222 on both sides of the perimeter wall 121 in a first direction is much greater than that of the shielding plates 1222 on both sides of the perimeter wall 121 in a second direction. Thus, the shielding plates 1222 arranging on four sides of the perimeter wall 121 can cover the heated plate 111 and the working component below the heated plate 11, playing a role of shielding so as to prevent the liquid-cooling medium leaking from the pipeline connected to the cold plate 11 from splashing onto the working component when dripping down to the liquid reservoir 13.

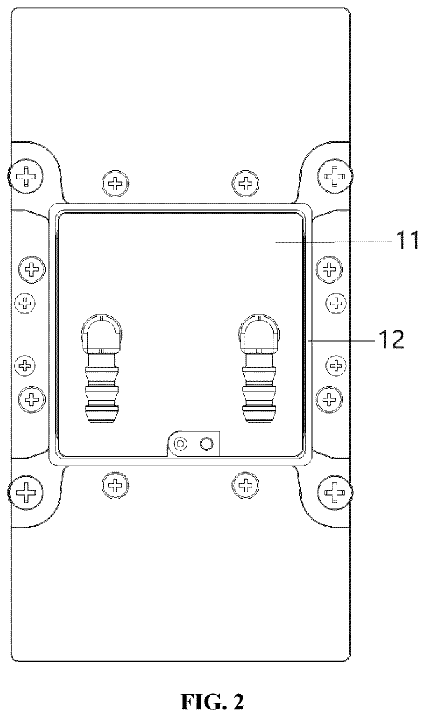

It should be noted that the first direction refers to a length direction of the structure shown in FIG. 2, and the second direction refers to a width direction of the structure shown in FIG. 2.

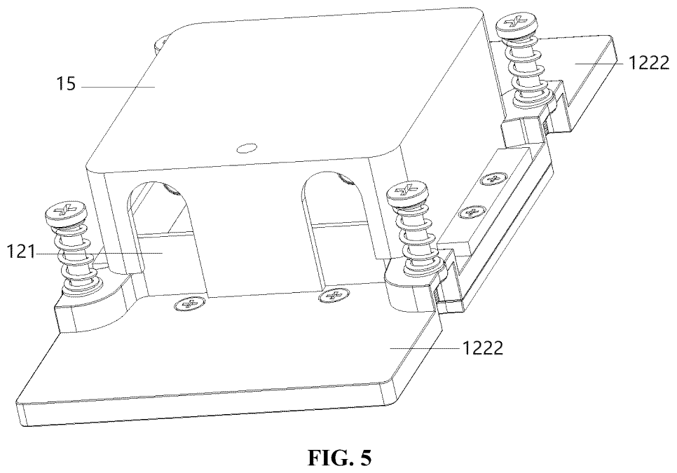

Referring to FIG. 5, in order to prevent the liquid-cooling medium in the liquid reservoir 13 from leaking, the liquid leakage protection device 1 further includes a cover 15. The cover 15 may be connected to the shielding plates 1222 by means of detachable connecting components (screws, bolts, etc.), and the cover 15 is disposed on the perimeter wall 121. The cover 15 can cover the upper opening of the perimeter wall 121 to prevent the liquid-cooling medium in the liquid reservoir 13 from leaking to the outside.

The cover 15 is provided with a hole through which a piping assembly passes to be connected to the cold plate 11. That is, the hole facilitates the connection between the piping assembly and the cold plate 11.

In some embodiments, the blocking part 122 or the enclosure structure 12 is of an integrated structure, for example, formed by injection molding or integrally formed of a metal material. The advantage of the integrated structure made of the metal material lies in dissipating heat from the working component of the server in addition to the function of shielding. The integrated structure of the blocking part 122 can also achieve a purpose of blocking the path along which the liquid-cooling medium in the liquid-cooling chamber 113 leaks to the working component.

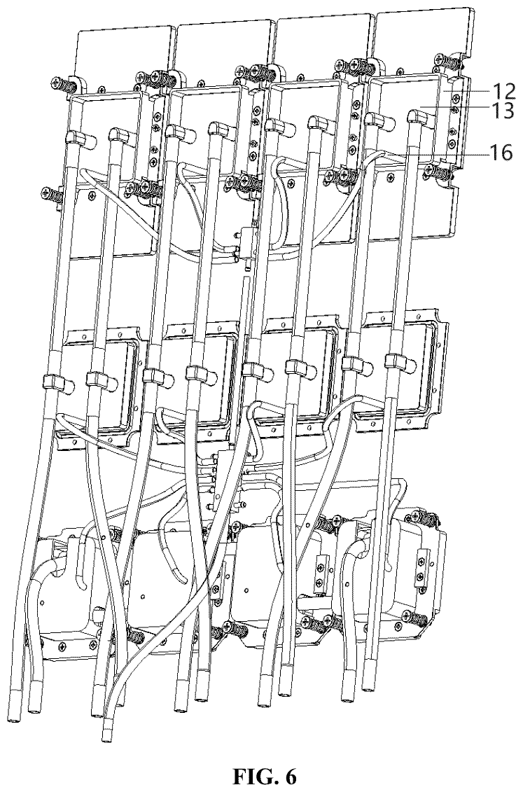

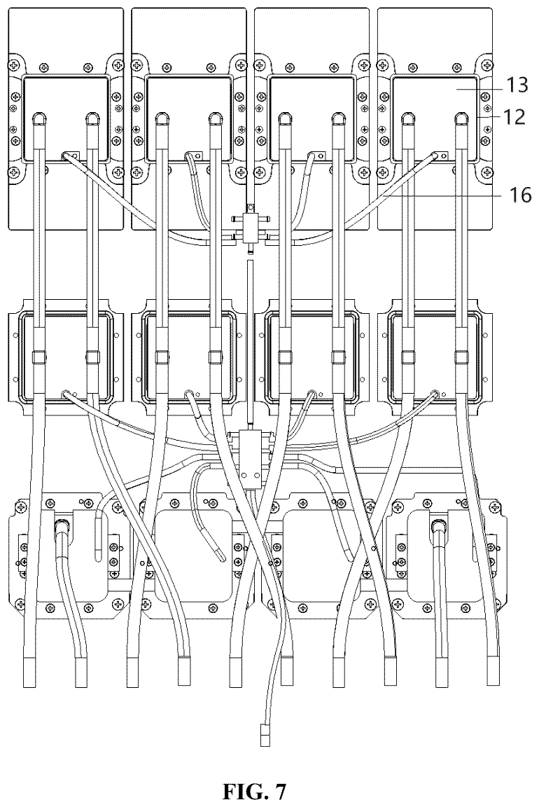

Referring to FIGS. 6 and 7, in order to further meet the protection requirements, the liquid leakage protection device 1 further includes a suction mechanism 16, which is connected to the liquid reservoir 13 to draw the liquid-cooling medium out of the liquid reservoir 13.

It can be understood that, compared with the existing solution that shuts down the equipment immediately after a liquid leakage occurs, the solution in this embodiment adopts the liquid reservoir 13 to store the leaking liquid-cooling medium after the liquid-cooling medium in the liquid-cooling chamber 113 leaks, thereby prolonging the time period from the beginning of leakage of liquid-cooling medium to the shutdown of the equipment, and postponing the shutdown of the equipment. On this basis, in order to further prolong the time period, the liquid cooling working medium in the liquid reservoir 13 may be further drawn by the suction mechanism 16 to prolong the protection time. In this way, the equipment may be shut down after clicking a data saving button on the equipment page and thus is beneficial to ensure data security.

In this embodiment, the suction mechanism 16 includes a liquid suction tube, a liquid suction assembly, a leakage detection member, and a control assembly.

The liquid suction tube may be arranged perpendicular to the cold plate 11, with one end of the liquid suction tube extending into the liquid reservoir 13. The liquid suction assembly is connected to the liquid suction tube, and draws the liquid-cooling medium in the liquid reservoir 13 through the liquid suction tube. The liquid suction assembly may be a liquid suction pump. The leakage detection member is located in the liquid reservoir 13, and is configured to detect the amount of the liquid-cooling medium in the liquid reservoir 13 and feedback a detected data to the control assembly. The control assembly is electrically connected to the leakage detection member and the liquid suction assembly. The control assembly is used to control the liquid suction assembly to start and draw the liquid-cooling medium in the liquid reservoir 13 when the amount of the liquid-cooling medium in the liquid reservoir 13 exceeds a warning level.

That is, the above-mentioned suction mechanism 16 is used to draw the liquid-cooling medium in the liquid reservoir 13 when the amount of liquid-cooling medium in the liquid reservoir 13 reaches a certain value, thereby facilitating the protection of server equipment.

In order to facilitate drawing the liquid-cooling medium out of the liquid reservoir 13, a liquid collection groove and a guide slope located around the liquid collection groove are provided on the cover plate 112. The liquid-cooling medium on the cover plate 112 is guided by the guide slope and then collected into the liquid collection groove. The liquid suction tube extends into the liquid collection groove. As such, the liquid suction assembly draws the liquid-cooling medium collected in the liquid collection groove through the liquid suction tube.

For example, the liquid collection groove may be located at the center of the cover plate 112 or at an edge of the cover plate 112. The location of the liquid collection groove is not limited in the present disclosure, as long as it can facilitate drawing the collected liquid.

In some embodiments, the leakage detection member may be a leakage detection sensor, and may be of a sheet-like structure. The leakage detection member in sheet-like structure covers a surface of the cover plate 112 away from the heated plate 111. As such, when the liquid-cooling medium is found at any position on the upper surface of the cover plate 112, the leakage detection member can detect it in real time and feedback a detected data to the control assembly.

According to actual assembling needs, the above-mentioned leakage detection member in sheet-like structure may be provided with several avoidance structures (e.g., avoidance grooves) to facilitate avoiding a structure arranged on the cover plate 112.

It should be noted that in the present disclosure, the relational terms such as first and second are only used to distinguish one entity from several other entities, and do not necessarily require or imply any actual relationship or order among these entities.

The above provides a detailed introduction to the dual port plugin provided in the present disclosure. This article applies specific examples to explain the principles and implementation methods of the present disclosure. The above examples are only used to help understand the methods and core ideas of the present disclosure. It should be pointed out that for ordinary technical personnel in this field, several improvements and modifications can be made to the present disclosure without departing from the principles of the present disclosure, and these improvements and modifications also fall within the scope of protection of the claims in the present disclosure.

1. A liquid leakage protection device, comprising:
a cold plate, wherein the cold plate comprises:
a heated plate; and
a cover plate, wherein the heated plate and the cover plate are connected to form a liquid-cooling chamber for accommodating a liquid-cooling medium; and
an enclosure structure arranged outside of the liquid-cooling chamber to block the liquid-cooling medium leaking from the liquid-cooling chamber from flowing to a working component in contact with the heated plate,
wherein the enclosure structure and the cold plate form a liquid reservoir, so that the liquid-cooling medium leaking from the liquid-cooling chamber is stored in the liquid reservoir.

2. The liquid leakage protection device according to claim 1, wherein a flow-guiding passage is further formed by the enclosure structure and the cold plate and is in communication with the liquid reservoir, and the flow-guiding passage is configured such that the liquid-cooling medium leaking from the liquid-cooling chamber flows into the liquid reservoir after being channeled through the flow-guiding passage.

3. The liquid leakage protection device according to claim 2, wherein the enclosure structure comprises:
a perimeter wall arranged around the cover plate to form the liquid reservoir; and
a blocking part connected to a bottom of the perimeter wall so as to form the flow-guiding passage and block a path along which the liquid-cooling medium in the liquid-cooling chamber leaks to the working component.

4. The liquid leakage protection device according to claim 3, wherein the blocking part comprises:
an outer edge arranged on the heated plate and extending beyond the cover plate;
a shielding plate arranged on an outer periphery of the perimeter wall and abutting against the outer edge; and
a seal retainer ring compressed between the outer edge and the shielding plate to seal a gap between the outer edge and the shielding plate.

5. The liquid leakage protection device according to claim 4, wherein a mounting groove is provided on the outer edge, the seal retainer ring is mounted in the mounting groove, and the mounting groove has a depth less than a thickness of the seal retainer ring.

6. The liquid leakage protection device according to claim 4, wherein the shielding plates are arranged on four sides of the perimeter wall, and a size of the shielding plates on both sides of the perimeter wall in a first direction is greater than that of the shielding plates on both sides of the perimeter wall in a second direction, so that the shielding plates cover the working component to prevent a liquid-cooling medium leaking from a pipeline connected to the cold plate from splashing onto the working components when dripping down to the liquid reservoir.

7. The liquid leakage protection device according to claim 3, further comprising a cover, wherein the cover is arranged on the perimeter wall to prevent the liquid-cooling medium in the liquid reservoir from leaking to the outside.

8. The liquid leakage protection device according to claim 1, further comprising a suction mechanism connected to the liquid reservoir to draw the liquid-cooling medium out of the liquid reservoir, wherein the suction mechanism comprises:
a liquid suction tube having an end extending into the liquid reservoir;
a liquid suction assembly connected to the liquid suction tube to draw the liquid-cooling medium out of the liquid reservoir through the liquid suction tube;
a leakage detection member arranged in the liquid reservoir to detect an amount of the liquid-cooling medium in the liquid reservoir; and
a control assembly electrically connected to the leakage detection member and the liquid suction assembly to control the liquid suction assembly to start and draw the liquid-cooling medium out of the liquid reservoir when the amount of the liquid-cooling medium in the liquid reservoir exceeds a warning amount.

9. The liquid leakage protection device according to claim 8, wherein a liquid collection groove and a guide slope located around the liquid collection groove are provided on the cover plate,
The guide slop is configured to guide the liquid-cooling medium on the cover plate to be collected into the liquid collection groove, and
the liquid suction tube extends into the liquid collection groove.

10. The liquid leakage protection device according to claim 8, wherein the leakage detection member is of a sheet-like structure, and covers a surface of the cover plate away from the heated plate.

11. The liquid leakage protection device according to claim 2, further comprising a suction mechanism connected to the liquid reservoir to draw the liquid-cooling medium out of the liquid reservoir, wherein the suction mechanism comprises:
a liquid suction tube having an end extending into the liquid reservoir;
a liquid suction assembly connected to the liquid suction tube to draw the liquid-cooling medium out of the liquid reservoir through the liquid suction tube;
a leakage detection member arranged in the liquid reservoir to detect an amount of the liquid-cooling medium in the liquid reservoir; and
a control assembly electrically connected to the leakage detection member and the liquid suction assembly to control the liquid suction assembly to start and draw the liquid-cooling medium out of the liquid reservoir when the amount of the liquid-cooling medium in the liquid reservoir exceeds a warning amount.

12. The liquid leakage protection device according to claim 3, further comprising a suction mechanism connected to the liquid reservoir to draw the liquid-cooling medium out of the liquid reservoir, wherein the suction mechanism comprises:
a liquid suction tube having an end extending into the liquid reservoir;
a liquid suction assembly connected to the liquid suction tube to draw the liquid-cooling medium out of the liquid reservoir through the liquid suction tube;
a leakage detection member arranged in the liquid reservoir to detect an amount of the liquid-cooling medium in the liquid reservoir; and
a control assembly electrically connected to the leakage detection member and the liquid suction assembly to control the liquid suction assembly to start and draw the liquid-cooling medium out of the liquid reservoir when the amount of the liquid-cooling medium in the liquid reservoir exceeds a warning amount.

13. The liquid leakage protection device according to claim 4, further comprising a suction mechanism connected to the liquid reservoir to draw the liquid-cooling medium out of the liquid reservoir, wherein the suction mechanism comprises:
a liquid suction tube having an end extending into the liquid reservoir;
a liquid suction assembly connected to the liquid suction tube to draw the liquid-cooling medium out of the liquid reservoir through the liquid suction tube;
a leakage detection member arranged in the liquid reservoir to detect an amount of the liquid-cooling medium in the liquid reservoir; and
a control assembly electrically connected to the leakage detection member and the liquid suction assembly to control the liquid suction assembly to start and draw the liquid-cooling medium out of the liquid reservoir when the amount of the liquid-cooling medium in the liquid reservoir exceeds a warning amount.

14. The liquid leakage protection device according to claim 5, further comprising a suction mechanism connected to the liquid reservoir to draw the liquid-cooling medium out of the liquid reservoir, wherein the suction mechanism comprises:
a liquid suction tube having an end extending into the liquid reservoir;
a liquid suction assembly connected to the liquid suction tube to draw the liquid-cooling medium out of the liquid reservoir through the liquid suction tube;
a leakage detection member arranged in the liquid reservoir to detect an amount of the liquid-cooling medium in the liquid reservoir; and
a control assembly electrically connected to the leakage detection member and the liquid suction assembly to control the liquid suction assembly to start and draw the liquid-cooling medium out of the liquid reservoir when the amount of the liquid-cooling medium in the liquid reservoir exceeds a warning amount.

15. The liquid leakage protection device according to claim 6, further comprising a suction mechanism connected to the liquid reservoir to draw the liquid-cooling medium out of the liquid reservoir, wherein the suction mechanism comprises:
a liquid suction tube having an end extending into the liquid reservoir;
a liquid suction assembly connected to the liquid suction tube to draw the liquid-cooling medium out of the liquid reservoir through the liquid suction tube;
a leakage detection member arranged in the liquid reservoir to detect an amount of the liquid-cooling medium in the liquid reservoir; and
a control assembly electrically connected to the leakage detection member and the liquid suction assembly to control the liquid suction assembly to start and draw the liquid-cooling medium out of the liquid reservoir when the amount of the liquid-cooling medium in the liquid reservoir exceeds a warning amount.

16. The liquid leakage protection device according to claim 7, further comprising a suction mechanism connected to the liquid reservoir to draw the liquid-cooling medium out of the liquid reservoir, wherein the suction mechanism comprises:
a liquid suction tube having an end extending into the liquid reservoir;
a liquid suction assembly connected to the liquid suction tube to draw the liquid-cooling medium out of the liquid reservoir through the liquid suction tube;
a leakage detection member arranged in the liquid reservoir to detect an amount of the liquid-cooling medium in the liquid reservoir; and
a control assembly electrically connected to the leakage detection member and the liquid suction assembly to control the liquid suction assembly to start and draw the liquid-cooling medium out of the liquid reservoir when the amount of the liquid-cooling medium in the liquid reservoir exceeds a warning amount.
